(19) United States
(12) Patent Application Publication
(10) Pub. No.: US 2025/0246472 A1
(43) Pub. Date: Jul. 31, 2025

(54) ELECTROSTATIC CHUCK

(71) Applicant: TOTO LTD., Fukuoka (JP)

(72) Inventors: Yuki SASAKI, Fukuoka (JP); Jun SHIRAISHI, Fukuoka (JP); Yutaka MOMIYAMA, Fukuoka (JP); Ikuo ITAKURA, Fukuoka (JP); Hitoshi SASAKI, Fukuoka (JP)

(21) Appl. No.: 19/034,362

(22) Filed: Jan. 22, 2025

(30) Foreign Application Priority Data
Jan. 25, 2024 (JP) 2024-009232

(51) Int. Cl. H01L 21/683; H01J 37/32

(52) U.S. Cl. CPC H01L 21/6833; H01J 37/32715; H01J 2237/2007; H01J 2237/334

(57) ABSTRACT

An electrostatic chuck includes a dielectric substrate, an RF electrode provided inside the dielectric substrate, and a base plate made of metal and joined to the dielectric substrate. The dielectric substrate includes a protrusion section protruding outward beyond a surface of the base plate in top view, and a part of the RF electrode is provided in the protrusion section.

### CROSS-REFERENCE TO RELATED APPLICATION

This application is based upon and claims the benefit of priority from Japanese Patent Application No. 2024-009232 filed on Jan. 25, 2024, the entire contents of which are incorporated herein by reference.

### FIELD

The present invention relates to an electrostatic chuck.

### BACKGROUND

For example, in a semiconductor manufacturing apparatus such as an etching apparatus, an electrostatic chuck is provided as an apparatus configured to attract and hold a wafer such as a silicon wafer to be processed. The electrostatic chuck includes a dielectric substrate to which an attraction electrode is provided and a base plate which supports the dielectric substrate, and has a configuration in which these are joined to each other. When a voltage is applied to the attraction electrode, an electrostatic force is generated, and the wafer placed on the dielectric substrate is attracted and held.

In the semiconductor manufacturing apparatus, RF electrodes are provided as a pair of counter electrodes for generating plasma. As described in Japanese Patent Laid-Open No. 2011-119654, the base plate of the electrostatic chuck is used as one of the RF electrodes in some cases. The RF electrodes are built in the dielectric substrate in some cases.

### SUMMARY

For example, a cured silicone adhesive is used as a joining layer which joins the dielectric substrate and the base plate. While a process such as etching is performed, an edge of the joining layer degrades through exposure to plasma and scatters, adversely affecting a wafer being processed in some cases.

To prevent such a situation, the inventors have been advancing development of an electrostatic chuck having a configuration in which the dielectric substrate is larger than a joined surface of the base plate, in other words, a configuration in which an outer circumferential edge of the dielectric substrate protrudes outward beyond the joined surface. With such a configuration, a member circumferentially covering the joining layer can be disposed on a lower side of the dielectric substrate. Accordingly, influence of the joining layer on a wafer being processed can be reduced.

In a case where the outer circumferential edge of the dielectric substrate protrudes outward beyond the joined surface, the base plate as an RF electrode is not present at a position in the dielectric substrate immediately below a protrusion part. Accordingly, plasma becomes ununiform immediately above the protrusion part, and a process such as etching is potentially not uniformly performed.

The present invention has been made in view of the above-mentioned issue and is aimed to provide an electrostatic chuck which can ensure plasma uniformity on an upper side of a dielectric substrate even with a configuration in which an outer circumferential edge of the dielectric substrate protrudes.

To address the above-mentioned issue, an electrostatic chuck according to the present invention includes a dielectric substrate including a placement surface on which an object to be attracted is placed, an RF electrode provided inside the dielectric substrate, and a base plate made of metal and joined to the dielectric substrate. The dielectric substrate includes a protrusion section protruding outward beyond a joined surface of the base plate when viewed from a direction perpendicular to the placement surface, and a part of the RF electrode is provided in the protrusion section.

Since a part of the RF electrode is provided in the protrusion section, almost the whole of a space immediately above the dielectric substrate (including a space immediately above the protrusion section) is sandwiched between a pair of electrodes including the RF electrode. Accordingly, plasma uniformity on an upper side of the dielectric substrate can be ensured.

According to the present invention, it is possible to provide an electrostatic chuck which can ensure plasma uniformity on an upper side of a dielectric substrate even with a configuration in which an outer circumferential edge of the dielectric substrate protrudes.

### BRIEF DESCRIPTION OF THE DRAWINGS

FIG. 1 is a cross sectional view schematically illustrating a configuration of an electrostatic chuck according to a first embodiment;

FIG. 2 is an expanded and detailed view of a part of the configuration in FIG. 1;

FIG. 3 is a cross sectional view illustrating a configuration of a part of an electrostatic chuck according to a modification of the first embodiment; and

FIG. 4 is a cross sectional view illustrating a configuration of a part of an electrostatic chuck according to a second embodiment.

### DETAILED DESCRIPTION

Hereinafter, the present embodiment will be described with reference to the accompanying drawings. To ease understanding of the descriptions, in each drawing, the same components are denoted by the same reference signs as much as possible, and duplicate descriptions are not repeated.

A first embodiment will be described. An electrostatic chuck 10 according to the present embodiment is configured to attract and hold a wafer W set as a process target by an electrostatic force inside a semiconductor manufacturing apparatus such as, for example, an etching apparatus which is not illustrated in the drawing. The wafer W that is an object to be attracted is, for example, a silicon wafer. The electrostatic chuck 10 may be used in an apparatus other than the semiconductor manufacturing apparatus.

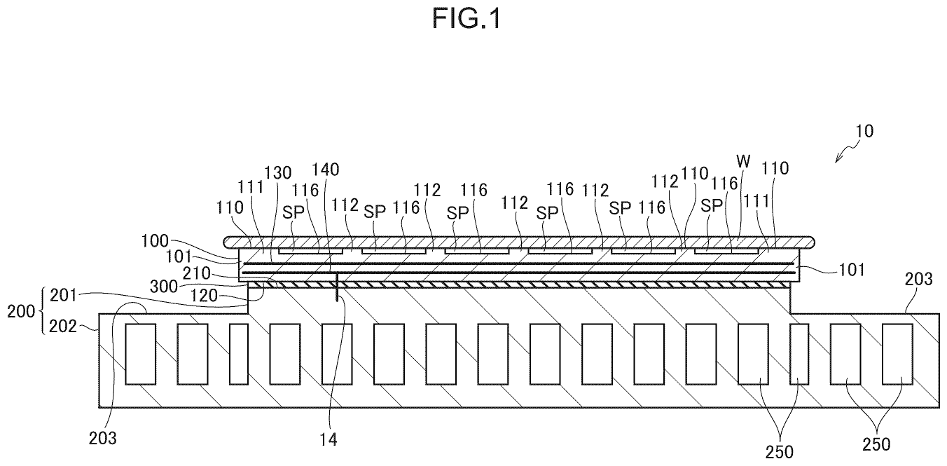

FIG. 1 is a cross sectional view schematically illustrating a configuration of the electrostatic chuck 10 in a state in which the wafer W is attracted and held. The electrostatic chuck 10 includes a dielectric substrate 100 and a base plate 200.

The dielectric substrate 100 is a substantially disk-shaped member formed of a ceramic sintered body. The dielectric substrate 100 contains, for example, highly pure aluminum oxide (Al₂O₃), but may contain other materials. A ceramics purity or type, an additive, or the like in the dielectric substrate 100 may be appropriately set by taking into account plasma resistance or the like needed for the dielectric substrate 100 in the semiconductor manufacturing apparatus. A diameter of the dielectric substrate 100 is, for example, 290 to 300 mm. A thickness of the dielectric substrate 100 is, for example, 0.5 to 3.0 mm.

A surface 110 on an upper side in FIG. 1 in the dielectric substrate 100 serves as a “placement surface” on which the wafer W is placed. A surface 120 on a lower side in FIG. 1 in the dielectric substrate 100 serves as a “surface to be joined” which is joined to the base plate 200 via a joining layer 300. A perspective in a case where the electrostatic chuck 10 is viewed from the surface 110 side along a direction perpendicular to the surface 110 will also be hereinafter expressed as “top view”.

An attraction electrode 130 is embedded inside the dielectric substrate 100. The attraction electrode 130 is a thin planar layer made of a metallic material such as, for example, tungsten, and is arranged so as to be parallel to the surface 110. As a material of the attraction electrode 130, molybdenum, platinum, palladium, and the like may be used in addition to tungsten. When a voltage is applied to the attraction electrode 130 from an outside via a feed line which is not illustrated in the drawing, an electrostatic force is generated between the surface 110 and the wafer W, and according to this, the wafer W is attracted and held. As a configuration of the above-described feed line, various configurations in related art can be adopted. The single attraction electrode 130 may be provided as so-called a “monopolar” electrode as in the present embodiment, but may also include two attraction electrodes as so-called “bipolar” electrodes. A depth of a position where the attraction electrode 130 is arranged, that is, a distance from a bottom 116 which will be described below to the attraction electrode 130 is, for example, 0.1 to 0.5 mm.

In addition to the above-described attraction electrode 130, an RF electrode 140 is embedded inside the dielectric substrate 100. The RF electrode 140 is provided as one of a pair of counter electrodes for generating plasma in the semiconductor manufacturing apparatus. The other of the counter electrodes is provided at a position on the upper side of the electrostatic chuck 10 in the semiconductor manufacturing apparatus. When high-frequency alternating-current voltage is applied between these counter electrodes, plasma is generated on the upper side of the wafer W and used for processing such as deposition and etching on the wafer W.

Similar to the attraction electrode 130, the RF electrode 140 is a thin planar layer made of a metallic material such as tungsten, for example. As a material of the RF electrode 140, molybdenum, platinum, palladium, and the like may be used in addition to tungsten. The RF electrode 140 is embedded at a position on the surface 120 side of the attraction electrode 130. Similar to the attraction electrode 130, the RF electrode 140 is disposed in parallel to the surface 110. The RF electrode 140 is a single electrode which is substantially circular in top view. In top view, a center of the RF electrode 140 matches a center of the dielectric substrate 100. A distance from the attraction electrode 130 to the RF electrode 140 is, for example, 0.2 to 2 mm. A distance from the RF electrode 140 to the surface 120 is, for example, 0.1 to 2.5 mm.

As illustrated in FIG. 1, a power supply path 14 is connected to the RF electrode 140. The power supply path 14 is an electric path provided to match a potential of the RF electrode 140 with a potential of the base plate 200 when high-frequency alternating-current voltage is applied between the RF electrode 140 and the other counter electrode. In FIG. 1, the power supply path 14 is entirely illustrated in a simplified manner. The power supply path 14 is configured as, for example, an electrode terminal formed with one end connected to the RF electrode 140 and the other end protruding downward from the surface 120. A protruding part of the power supply path 14 as described above is embedded in a non-illustrated recessed part formed in a surface 210 of the base plate 200 and is connected to a metal part of the base plate 200. The number of power supply paths 14 may be equal to or larger than two.

As illustrated in FIG. 1, a space SP is formed between the dielectric substrate 100 and the wafer W. When a process such as etching is performed in the semiconductor manufacturing apparatus, a helium gas for temperature regulation is supplied to the space SP from the outside via a gas hole which is not illustrated in the drawing. When the helium gas is caused to be present between the dielectric substrate 100 and the wafer W, a thermal resistance between the dielectric substrate 100 and the wafer W is regulated, and according to this, a temperature of the wafer W is maintained at an appropriate temperature. It is noted that the gas for temperature regulation to be supplied to the space SP may be a gas of a type different from helium.

A seal ring 111 and a dot 112 are provided on the surface 110 which serves as the placement surface, and the space SP described above is formed around the seal ring 111 and the dot 112.

The seal ring 111 is a wall which defines the space SP in a position corresponding to an outermost circumference. The seal ring 111 is an annular protrusion formed on the surface 110 side. A distal end (upper end in FIG. 1) of the seal ring 111 is a part of the surface 110 and contacts the wafer W. The distal end of the seal ring 111 can be referred to as a part on an outermost circumferential side on the surface 110 which serves as the placement surface.

It is noted that the seal ring 111 may include a plurality of seal rings 111 provided so as to divide the space SP. With such a configuration, a pressure of the helium gas in each of the spaces SP can be individually regulated, and a surface temperature distribution of the wafer W during the process can be set to be close to uniform.

A part denoted by a reference sign “116” in FIG. 1 is a bottom of the space SP. Hereinafter, this part may also be referred to as a “bottom 116”. The seal ring 111 is formed as a result of digging a part of the surface 110 to a position of the bottom 116 together with the dot 112 which will be described next.

The dot 112 is a circular protrusion which protrudes from the bottom 116. The dot 112 includes a plurality of dots 112 to be provided. The plurality of dots 112 are substantially uniformly distributed and arranged on the placement surface of the dielectric substrate 100. A tip of each of the dots 112 becomes a part of the surface 110 and abuts against the wafer W. By providing the plurality of thus configured dots 112, warping of the wafer W is reduced.

The base plate 200 is a substantially disk-shaped member which supports the dielectric substrate 100. The base plate 200 is made of, for example, a metallic material such as aluminum. The base plate 200 is joined to the surface 120 of the dielectric substrate 100 via the joining layer 300. A surface 210 on the upper side in FIG. 1 in the base plate 200 serves as a “surface to be joined” which is joined to the dielectric substrate 100 via the joining layer 300.

The joining layer 300 is a layer provided between the dielectric substrate 100 and the base plate 200 to join those components. The joining layer 300 is provided by causing an adhesive made of an insulating material to be cured. According to the present embodiment, a silicone adhesive is used as the above-described adhesive. It is noted however that the joining layer 300 may be provided by causing an adhesive made of other types to be cured. In any case, in order that a thermal resistance between the dielectric substrate 100 and the base plate 200 is reduced, a material with a highest possible thermal conductivity may be used as the material of the joining layer 300.

The base plate 200 includes a support section 201 and a flange section 202. The support section 201 is an upper part in FIG. 1 of the base plate 200 and is a substantially cylindrical part which directly supports the dielectric substrate 100 from below. Similar to the dielectric substrate 100, a diameter of the support section 201, in other words, a diameter of the surface 210 is, for example, 290 to 300 mm but slightly smaller than the diameter of the dielectric substrate 100. A thickness of the support section 201, that is, an amount of protrusion of the support section 201 which faces upwards in FIG. 1 (amount of protrusion from the flange section 202) is, for example, 3 to 15 mm.

The flange section 202 is a lower part in FIG. 1 of the base plate 200. A shape of the flange section 202 is a substantially cylindrical shape, and a central axis of the flange section 202 matches a central axis of the support section 201. A diameter of the flange section 202 is larger than the diameter of the support section 201. An amount of protrusion of the flange section 202 from a lateral surface of the support section 201 (that is, an amount of protrusion in a radial direction) is, for example, 20 to 30 mm. A thickness of the flange section 202 is, for example, 25 to 40 mm. An entire thickness of the base plate 200 including the support section 201 and the flange section 202 is, for example, 30 to 40 mm.

When a process on the wafer W is to be performed in the semiconductor manufacturing apparatus, a focus ring which is not illustrated in the drawing is installed on an upper surface 203 of the flange section 202. The focus ring is an annular and plate-like member made of an insulating material such as quartz, for example, and is installed for a purpose of regulating a distribution of plasma during the process. Almost the whole of the dielectric substrate 100 and the support section 201 may be surrounded by the focus ring from an outer circumferential side, accordingly.

A coolant flow path 250 through which a coolant flows is formed inside the base plate 200. When the process such as etching is performed in the semiconductor manufacturing apparatus, the coolant is supplied from the outside to the coolant flow path 250, and according to this, the base plate 200 is cooled down. Heat generated in the wafer W during the process is transferred to the coolant via the helium gas in the space SP, the dielectric substrate 100, and the base plate 200, and the heat is exhausted to the outside together with the coolant.

As described above, in the electrostatic chuck 10 according to the present embodiment, the diameter of the support section 201 serving as a part of the base plate 200, which directly supports the dielectric substrate 100 is smaller than the diameter of the dielectric substrate 100. As a result, the dielectric substrate 100 protrudes outward beyond the surface 210 serving as the joined surface. Such a protruding part of the dielectric substrate 100 will also be hereinafter referred to as “protrusion section 101”. An amount of protrusion of the protrusion section 101, in other words, an amount of protrusion of the dielectric substrate 100 from the lateral surface of the support section 201 (that is, an amount of protrusion in the radial direction) is, for example, 1 mm to 3 mm.

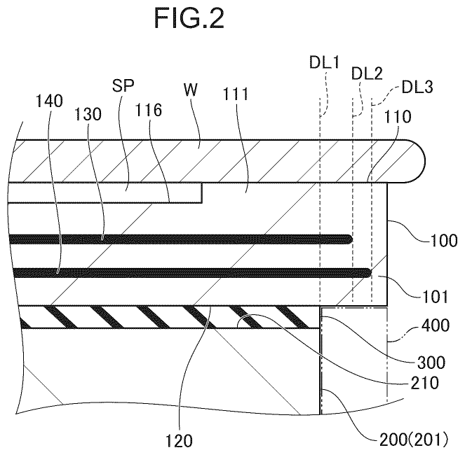

While a process such as etching is performed, an edge of the joining layer 300 degrades through exposure to plasma and scatters, adversely affecting the wafer W being processed in some cases. In a case where the protrusion section 101 is provided in the dielectric substrate 100 as in the present embodiment, a member circumferentially covering the exposed part of the joining layer 300 can be disposed on the lower side of the dielectric substrate 100. In FIG. 2, an example of a disposition place of such a member is illustrated with a dashed and single-dotted line denoted by a reference sign “400”. By disposing the member, it is possible to reduce influence of the joining layer 300 on the wafer W being processed.

During a process such as etching, it may be required to ensure plasma uniformity on the upper side of the dielectric substrate 100 so that the process is uniformly performed. In a case where the dielectric substrate 100 is not provided with the protrusion section 101 and the surface 120 of the dielectric substrate 100 is entirely supported from below by the base plate 200, it is possible to ensure plasma uniformity in the whole of a space immediately above the surface 110, for example, by enabling the base plate 200 to function as an RF electrode. However, in a case where the dielectric substrate 100 is provided with the protrusion section 101 as in the present embodiment, the base plate 200 as an RF electrode is not present at a position immediately below the protrusion section 101. Accordingly, plasma may become ununiform immediately above the protrusion section 101, and the process such as etching may be potentially not uniformly performed.

Thus, in the electrostatic chuck 10 according to the present embodiment, the RF electrode 140 is provided inside the dielectric substrate 100, and disposition of the RF electrode 140 may be contrived to ensure plasma uniformity during a process.

FIG. 2 illustrates a configuration of the protrusion section 101 and its vicinity part in the electrostatic chuck 10 in FIG. 1 in an enlarged and detailed manner. A dotted line DL1 illustrated in FIG. 2 represents a position of an outer circumferential edge of the surface 210 serving as the joined surface. A dotted line DL2 represents a position of an outer circumferential edge of the attraction electrode 130. A dotted line DL3 represents a position of an outer circumferential edge of the RF electrode 140.

The “outer circumferential edge” of the RF electrode 140 is a part where a smallest circle encompassing the entire RF electrode 140 overlaps the RF electrode 140 in top view. The “outer circumferential edge” of the attraction electrode 130 is similarly defined.

A diameter of the outer circumferential edge of the RF electrode 140 is larger than the diameter of the surface 210 of the base plate 200. Accordingly, the outer circumferential edge (dotted line DL3) of the RF electrode 140 extends into the protrusion section 101 of the dielectric substrate 100.

As in the present embodiment, with a configuration in which a part of the RF electrode 140 is provided in the protrusion section 101, almost the whole of the space immediately above the dielectric substrate 100 (including a space immediately above the protrusion section 101) is sandwiched between a pair of electrodes including the RF electrode 140. Thus, the RF electrode 140 can be enlarged to a range larger than the surface 210 of the base plate 200 even with the protrusion section 101 provided in the dielectric substrate 100. Accordingly, plasma uniformity on the upper side of the dielectric substrate 100 can be ensured.

Moreover, in the present embodiment, a diameter of the outer circumferential edge of the attraction electrode 130 is larger than the diameter of the surface 210 of the base plate 200. Accordingly, not only a part of the RF electrode 140 but also a part of the attraction electrode 130 extend into the protrusion section 101 in top view.

With this configuration in which a part of the attraction electrode 130 is provided in the protrusion section 101, attraction force of the protrusion section 101 on the wafer W increases, and both members closely contact with a strong force. Although the base plate 200 which is a cooling material is not present immediately below the protrusion section 101, heat resistance between the protrusion section 101 and the wafer W decreases, and thus temperature increase of the wafer W immediately above the protrusion section 101 can be reduced to some extent. As a result, variation in an in-plane temperature distribution of the wafer W during a process can be reduced.

The diameter of the outer circumferential edge of the attraction electrode 130 is larger than a diameter of the seal ring 111 on an inner circumferential side and smaller than a diameter of the seal ring 111 on the outer circumferential side. The diameter of the seal ring 111 on the outer circumferential side is larger than the diameter of the surface 210 of the base plate 200. A part of the seal ring 111 overlaps both the protrusion section 101 and the attraction electrode 130 in top view. Since the seal ring 111, the protrusion section 101, and the attraction electrode 130 are placed over in top view, cooling of the wafer W in this part can be further improved. As a result, variation in the in-plane temperature distribution of the wafer W can be further reduced.

Not a part of the seal ring 111 but its entirety may overlap both the protrusion section 101 and the attraction electrode 130 in top view. In this case, the diameter of the seal ring 111 on the inner circumferential side may be larger than the diameter of the support section 201. In addition, the diameter of the seal ring 111 on the outer circumferential side may be smaller than the diameter of the dielectric substrate 100 and smaller than the diameter of the outer circumferential edge of the attraction electrode 130.

In any case, a distance from the outer circumferential edge (dotted line DL2) of the attraction electrode 130 to a lateral surface of the dielectric substrate 100 may be approximately 0.1 mm to 3 mm. By ensuring a distance of this magnitude, a dielectric breakdown between the attraction electrode 130 and an outside may be prevented.

The diameter of the outer circumferential edge (dotted line DL3) of the RF electrode 140 is larger than the diameter of the outer circumferential edge (dotted line DL1) of the attraction electrode 130. Accordingly, the RF electrode 140 is provided in a range where its outer circumferential edge is positioned on the outer circumferential side of the outer circumferential edge of the attraction electrode 130 in top view. A distance from the outer circumferential edge (dotted line DL3) of the RF electrode 140 to the lateral surface of the dielectric substrate 100 may be approximately 0.1 mm to 2 mm.

The potential of the RF electrode 140 during a process is typically set to be lower than a potential of the attraction electrode 130. When the outer circumferential edge of the RF electrode 140 extends outward beyond the outer circumferential edge of the attraction electrode 130 as in the present embodiment, the RF electrode 140 can be provided over as wide an area as possible within a range that ensures withstand voltage. As a result, plasma uniformity can be ensured.

As described above, the diameter of the outer circumferential edge of the RF electrode 140 may be set to be larger than the diameter of the joined surface (surface 210) of the base plate 200. The “joined surface” is a surface of the metal part of the base plate 200, which faces the dielectric substrate through the joining layer 300. The “joined surface” can be defined in the same manner as described above in a case where the surface 210 is covered by an insulating film.

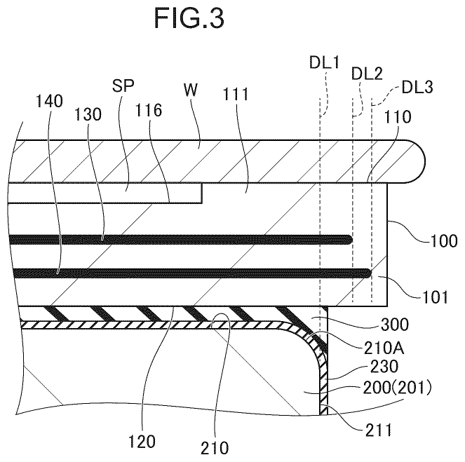

For example, in a modification illustrated in FIG. 3, an insulating film 230 is formed to cover a surface of the base plate 200 including the surface 210. The insulating film 230 is, for example, an alumina film formed by thermal spraying. A thickness of the insulating film is, for example, 1 mm or smaller.

In the modification in FIG. 3, a part in the vicinity of an edge of the surface 210 on the outer circumferential side is not a flat surface but is a surface curved in a circular arc shape. Such a curved surface part of the surface 210 will also be hereinafter referred to as a “surface 210A”. In the modification, the whole of the surface 210 including the surface 210A is defined as the “joined surface” which is joined to the dielectric substrate 100 through the insulating film 230 and the joining layer 300.

The lateral surface of the support section 201 is denoted by a reference sign “211” in FIG. 3. This lateral surface will also be hereinafter referred to as a “lateral surface 211”. In top view, a position (dotted line DL1) of an outer circumferential edge of the joined surface matches a position of the lateral surface 211.

In a case where the surface of the base plate 200 is covered by the insulating film 230 as in the modification, a part of the dielectric substrate 100 on the outside of the dotted line DL1 in top view corresponds to the protrusion section 101. The attraction electrode 130 and the RF electrode 140 are formed to extend to positions on the outside of the dotted line DL1.

A second embodiment will be described below. In the following, features different from those of the first embodiment will be mainly described, and description of features common to those of the first embodiment is omitted as appropriate.

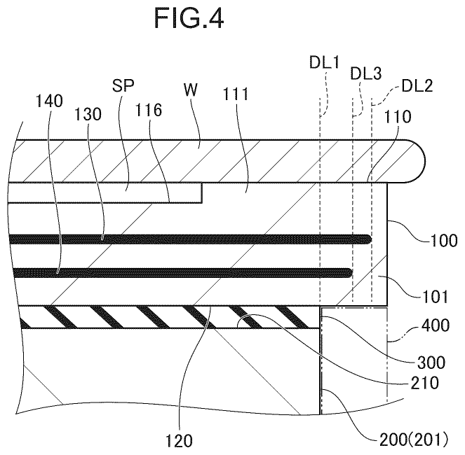

FIG. 4 illustrates a configuration of the electrostatic chuck 10 according to the present embodiment from the same viewpoint as in FIG. 2. As illustrated in FIG. 4, in the present embodiment, the diameter of the outer circumferential edge (dotted line DL3) of the RF electrode 140 is smaller than the diameter of the outer circumferential edge (dotted line DL2) of the attraction electrode 130. Accordingly, the RF electrode 140 is provided in a range where its outer circumferential edge is positioned on the inner circumferential side of the outer circumferential edge of the attraction electrode 130 in top view.

While a process is performed on the wafer W, Joule heat is generated in the RF electrode 140 and increases temperature of surrounding members in some cases. Accordingly, the RF electrode 140 can act as a heat generating source during the process. Thus, in the present embodiment as described above, the RF electrode 140 is provided in a range where its outer circumferential edge is positioned inside the outer circumferential edge of the attraction electrode 130. Since the RF electrode 140 as a heat generating source is provided in the above-described range, temperature increase at a part of the wafer W on the outer circumferential side can be reduced.

The outer circumferential edge of the RF electrode 140 may overlap the outer circumferential edge of the attraction electrode 130 in top view. In other words, the RF electrode 140 may be provided in a range where its outer circumferential edge does not protrude beyond the outer circumferential edge of the attraction electrode 130.

If heat generation from the RF electrode 140 would be caused with a configuration in which the outer circumferential edge of the RF electrode 140 extends into the protrusion section 101, the configuration of the present embodiment may be employed in place of that of the first embodiment.

The present embodiment has been described above with reference to the specific examples. However, the present disclosure is not limited to these specific examples. Configurations obtained by adding appropriate design modifications to these specific examples by a person skilled in the art are also within the scope of the present disclosure as long as the configurations have a feature of the present disclosure. Each of the elements included in each of the specific examples described above and arrangements, conditions, shapes, and the like of the elements are not limited to those illustrated and can be modified as appropriate. For each of the elements included in each of the specific examples described above, a combination can be appropriately changed as long as a technical contradiction does not occur.

What is claimed is:

1. An electrostatic chuck comprising:
a dielectric substrate including a placement surface on which an object to be attracted is placed;
an RF electrode provided inside the dielectric substrate; and
a base plate made of metal and joined to the dielectric substrate, wherein
the dielectric substrate includes a protrusion section protruding outward beyond a joined surface of the base plate when viewed from a direction perpendicular to the placement surface, and
a part of the RF electrode is provided in the protrusion section.

2. The electrostatic chuck according to claim 1, further comprising an attraction electrode provided inside the dielectric substrate, wherein a part of the attraction electrode is provided in the protrusion section when viewed from the direction perpendicular to the placement surface.

3. The electrostatic chuck according to claim 2, wherein the RF electrode is provided in a range where an outer circumferential edge of the RF electrode is positioned on an outer circumferential side of an outer circumferential edge of the attraction electrode when viewed from the direction perpendicular to the placement surface.

4. The electrostatic chuck according to claim 2, wherein the RF electrode is provided in a range where an outer circumferential edge of the RF electrode does not protrude beyond an outer circumferential edge of the attraction electrode when viewed from the direction perpendicular to the placement surface.

5. The electrostatic chuck according to claim 1, further comprising:
an insulating film on the joined surface and a lateral surface of the base plate, the dielectric substrate being spaced from the base plate by a portion of the insulating film.
